(19) United States
(12) Patent Application Publication
(10) Pub. No.: US 2009/0314540 A1
(43) Pub. Date: Dec. 24, 2009

(54) Composite housing using biodegradable plastics and manufacturing method thereof

(75) Inventor: Yasushi Yui, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/461,916

(22) Filed: Aug. 27, 2009

Related U.S. Application Data
(63) Continuation of application No. PCT/JP2007/057211, filed on Mar. 30, 2007.

(51) Int. Cl. H05K 7/14; H05K 5/02; B29C 45/14

(52) U.S. Cl. 174/535; 174/50; 264/271.1

(57) ABSTRACT

A composite housing using biodegradable plastics comprises: a metallic plate; a layer of adhesive coated on an inner face of the metallic plate; and a layer of biodegradable plastics laminated on a coating face of the layer of adhesive coated on the metallic plate, wherein the metallic plate is formed into a profile of a housing, an inner face of the formed metallic plate is coated with adhesive, the metallic plate is fitted into a female metallic mold, and biodegradable plastics are injected into a cavity formed between the adhesive coating face of the metallic plate and a male metallic mold so that the metallic plate and the biodegradable plastics are integrated with each other in the metallic mold into one body. A boss is provided in the biodegradable plastics and a circuit board can be attached onto the boss.

### CROSS-REFERENCE TO RELATED APPLICATION

This application is a continuation application based upon and claims priority of International application No. PCT/JP2007/057211, filed on Mar. 30, 2007, the contents being incorporated herein by reference.

### FIELD

The present invention relates to a composite housing using biodegradable plastics and a manufacturing method thereof. More particularly, the present invention relates to a composite housing and a manufacturing method thereof, in which a metallic plate and biodegradable plastics are used, heat radiating property and electromagnetic wave cut-off property of which are excellent and further mechanical strength of which is high.

### BACKGROUND

Recently, housings of information devices such as personal computers and mobile phones are made of plastics in many cases because plastics are easily formable. On the other hand, many parts integrated into these information devices have higher heating values because of improvement in performance, high integration of parts and high speed of operation. Accordingly, the information devices generate a lot of heat and noise during operation.

However, in a housing made of plastics, the heat generated by the information device is cut off. Therefore, a temperature in the information device increases high. Then, the malfunction of the information device tends to occur due to the heat generated by electronic parts. Since the housing made of plastics does not shield electromagnetic waves, the following problems may occur. The internal parts of the information device are erroneously operated by the electromagnetic waves sent from the outside. On the contrary, the electromagnetic waves generated by the internal parts of the information device leak outside and devices arranged in the periphery of the information device are affected and trouble may occur.

On the other hand, in order to prevent heat from affecting the information device, i.e., in order to insulate heat or radiate heat and further in order to prevent electromagnetic waves from affecting the information device, a housing of the information device may be made of a metallic material. Since metal has good heat conduction, it is possible for metal to effectively radiate heat. Further, it is possible for metal to shield electromagnetic waves. However, metal is heavy and is expensive. Furthermore, when the plate thickness is large, it is difficult to form a metallic plate into a housing of a desired profile.

In order to solve the above problems, a technique of making a composite housing is proposed in Official gazette of JP-A-2001-315159 in which both the advantage of the metal and the advantage of plastics are effectively used, which will be described as follows. A metallic plate, at least one side of which is covered with plastics, is fitted and fixed into a cavity of a metallic mold for injection molding. Melted plastics are injected onto a face, which is covered with plastics, of this metallic plate so as to form an injection molding portion. In this way, the metallic plate and the injection molding portion are integrated with each other into one body of the composite housing. Specifically, a composite housing is proposed in which a metallic plate is covered with polyester resin and plastics in which polycarbonate and ABS are mixed with each other and injected to form a profile.

In this connection, in recent years, in the field of the information devices such as personal computers and mobile phones, techniques of recycling products and reusing resources have been actively developed and applied because of the enforcement of the law of recycling domestic electric appliances and the enforcement of the law of regulating the environment. Therefore, even in the aforementioned technique in which the plastics and the metal are integrated with each other into one body, it is preferable to use vegetable biodegradable plastics, the recycling and the environmental property of which are high, for the plastics used for the housing of the information device.

### SUMMARY

However, the conventional composite housing, in which a metallic plate and an injection molding portion are integrated with each other into one body, does not use biodegradable plastics but uses petroleum plastics such as polycarbonate or ABS. Therefore, the conventional composite housing is low in the recycling and the environmental property. Therefore, it is possible to consider to compose the composite housing disclosed in Official gazette of JP-A-2001-315159 by using biodegradable plastics instead of petroleum plastics.

However, when the composite housing is made of biodegradable plastics instead of petroleum plastics, the adhesion between the metal and the biodegradable plastics are not good. Therefore, the mechanical strength of the composite housing is not sufficiently high and the biodegradable plastics tends to be peeled off.

An object of the present invention is to provide a composite housing and a manufacturing method thereof in which biodegradable plastics are used, the adhesion property with a metallic plate of which is excellent and the recycling and the environmental property of which are high.

In order to accomplish the above object, the present invention provides a composite housing using biodegradable plastics comprising: a metallic plate; a layer of adhesive coated on an inner face of the metallic plate; and a layer of biodegradable plastics laminated on a coating face of the layer of adhesive coated on the metallic plate, wherein the metallic plate is formed into a profile of a housing, an inner face of the formed metallic plate is coated with adhesive, the metallic plate is fitted into a female metallic mold, and biodegradable plastics are injected into a cavity formed between the adhesive coating face of the metallic plate and a male metallic mold so that the metallic plate and the biodegradable plastics are integrated with each other into one body in the metallic mold.

In this case, the male metallic mold of a predetermined portion in the metallic mold can be tightly contacted with an adhesive coating face of the metallic plate so as to form a discontinuous portion in a cavity in the metallic mold and the metallic plate can be exposed to a portion corresponding to the discontinuous portion of the cavity on the inner face of the composite housing which has been integrally molded into one body. When at least two cavities for forming a boss having a screw hole are provided in the cavity in the metallic mold, bosses, to which a circuit board on which electronic parts are mounted can be attached, can be formed on an inner face of the composite housing after the completion of integral forming.

In order to accomplish the above object, the present invention provides a method of manufacturing a composite housing using biodegradable plastics which includes a metallic plate, a layer of adhesive coated on an inner face of the metallic plate, and a layer of biodegradable plastics laminated on a coating face of the layer of adhesive coated on the metallic plate, the method of manufacturing the composite housing using biodegradable plastics comprising: a step of forming the metallic plate into a profile of a housing; a step of coating adhesive on an inner face of the formed metallic plate; a step of fitting the metallic plate, on the inner face of which adhesive is coated, into a female metallic mold; a step of injecting biodegradable plastics into a cavity between an adhesive coating face of the metallic plate and a male metallic mold; and a step of taking out a compound housing from the metallic mold after cooling.

According to the composite housing using biodegradable plastics and the manufacturing method thereof of the present invention for accomplishing the above object, it is possible to enhance the adhesion property between the metallic plate and biodegradable plastics and further it is possible to enhance the resource reusing property, the recycling property and the environment property. Accordingly, it is possible to enhance the reliability of the composite housing can be enhanced.

### BRIEF DESCRIPTION OF DRAWINGS

FIGS. 1A to 1E are views depicting a manufacturing process of the composite housing of the first embodiment of the present invention. FIG. 1A is a sectional view of the metallic plate before forming, FIG. 1B is a sectional view of the metallic plate after forming, FIG. 1C is a sectional view depicting a state in which adhesive is coated on an inner face of the metallic plate after forming, FIG. 1D is a sectional view depicting a state in which the metallic plate depicted in FIG. 1C is fitted into a metallic mold and biodegradable plastics are injected into a cavity, and FIG. 1E is a sectional view of the composite housing of the first embodiment integrally formed in a metallic mold.

FIGS. 2A to 2C are views depicting a manufacturing process of the composite housing of the second embodiment of the present invention. FIG. 2A is a sectional view depicting a state in which a metallic plate, on the inner face of which adhesive is coated after forming, is fitted into a metallic mold and biodegradable plastics are injected into a cavity, FIG. 2B is a sectional view of the composite housing of the second embodiment integrally formed in a metallic mold, and FIG. 2C is a sectional view depicting a state in which a circuit board, on which electronic parts are mounted, is attached to the composite housing depicted in FIG. 2B.

FIGS. 3A to 3C are views depicting a manufacturing process of the composite housing of the third embodiment of the present invention. FIG. 3A is a sectional view depicting a state in which a metallic plate, on the inner face of which adhesive is coated after forming, is fitted into a metallic mold and biodegradable plastics are injected into a cavity, FIG. 3B is a sectional view of the composite housing of the second embodiment integrally formed in a metallic mold, and FIG. 3C is a sectional view depicting a state in which a circuit board, on which electronic parts are mounted, is attached to the composite housing depicted in FIG. 3B.

FIGS. 4A to 4C are views depicting a manufacturing process of the composite housing of the fourth embodiment of the present invention. FIG. 4A is a sectional view depicting a state in which a metallic plate, on the inner face of which adhesive is coated after forming, is fitted into a metallic mold and biodegradable plastics are injected into a cavity, FIG. 4B is a sectional view of the composite housing of the second embodiment integrally formed in a metallic mold, and FIG. 4C is a sectional view depicting a state in which a circuit board, on which electronic parts are mounted, is attached to the composite housing depicted in FIG. 4B.

FIGS. 5A to 5C are view depicting a manufacturing process of the composite housing of the fifth embodiment of the present invention. FIG. 5A is a sectional view depicting a state in which a metallic plate, on the inner face of which adhesive is coated after forming, is fitted into a metallic mold and biodegradable plastics are injected into a cavity, FIG. 5B is a sectional view of the composite housing of the second embodiment integrally formed in a metallic mold, and FIG. 5C is a sectional view depicting a state in which a circuit board, on which electronic parts are mounted, is attached to the composite housing depicted in FIG. 5B.

FIGS. 6A to 6C are views depicting a manufacturing process of the composite housing of the sixth embodiment of the present invention. FIG. 6A is a sectional view depicting a state in which a metallic plate, on the inner face of which adhesive is coated after forming, is fitted into a metallic mold and biodegradable plastics are injected into a cavity, FIG. 6B is a sectional view of the composite housing of the second embodiment integrally formed in a metallic mold, and FIG. 6C is a sectional view depicting a state in which a circuit board, on which electronic parts are mounted, is attached to the composite housing depicted in FIG. 6B.

FIGS. 7A to 7C are views depicting a manufacturing process of the composite housing of the seventh embodiment of the present invention. FIG. 7A is a sectional view depicting a state in which a metallic plate, on the inner face of which adhesive is coated after forming, is fitted into a metallic mold and biodegradable plastics are injected into a cavity, FIG. 7B is a sectional view of the composite housing of the second embodiment integrally formed in a metallic mold, and FIG. 7C is a sectional view depicting a state in which a circuit board, on which electronic parts are mounted, is attached to the composite housing depicted in FIG. 7B and further a metallic tape for radiating heat is attached inside and outside of the housing.

FIGS. 8A to 8C are views depicting a manufacturing process of the composite housing of the eighth embodiment of the present invention. FIG. 8A is a sectional view depicting a state in which a metallic plate, on the inner face of which adhesive is coated after forming, is fitted into a metallic mold and biodegradable plastics are injected into a cavity, FIG. 8B is a sectional view of the composite housing of the second embodiment integrally formed in a metallic mold, and FIG. 8C is a sectional view depicting a state in which a circuit board, on which electronic parts are mounted, is attached to the composite housing depicted in FIG. 8B and further a metallic tape for radiating heat is attached inside and outside of the housing.

FIGS. 9A to 9C are views depicting an example of the use of the composite housing of the present invention in which biodegradable plastics are used. FIG. 9A is a perspective view depicting an example in which a composite housing of the present invention is used for a back cover of a note type personal computer, FIG. 9B is a perspective view depicting an example in which a composite housing of the present invention is used for a lower bar and an upper cover of a body of a mobile phone, and FIG. 9C is a perspective view depicting an example in which a composite housing of the present invention is used for a back cover of a body of PDA.

### DESCRIPTION OF EMBODIMENTS

Referring to the drawings, a preferable embodiment of the present invention will be illustrated below. Even in a different embodiment, like reference marks are used to indicated like components. In the drawings depicting the embodiment, the scales in the thickness direction of a metallic plate, a layer of adhesive and a layer of biodegradable plastics are depicted different from the actual scales.

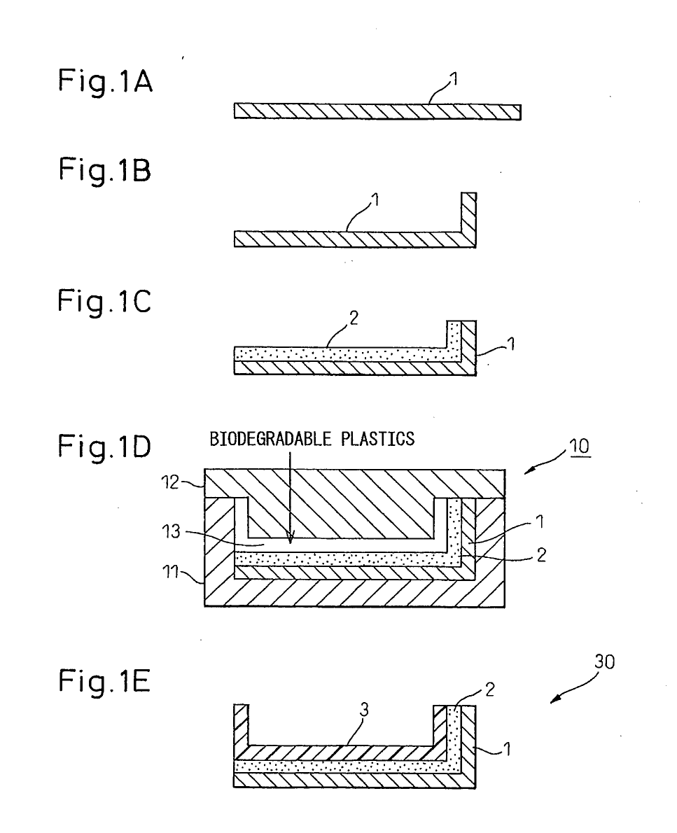

FIGS. 1A to 1E are views depicting a manufacturing process of the composite housing of the first embodiment of the present invention. In the case of manufacturing the composite housing, first, the metallic plate 1 depicted in FIG. 1A is prepared. It is desirable that the plate thickness of this metallic plate 1 is not more than 10 mm. This metallic plate 1 is subjected to cutting, folding and perforating so that it can be formed into an arbitrary profile. In order to simplify the explanations, in the case of the first embodiment, FIG. 1B depicts the metallic plate 1 which has been subjected to only folding.

Next, as depicted in FIG. 1C, the adhesive 2 is coated on an inner face of the folded metallic plate 1. Concerning the adhesive 2, the acrylic adhesive, the epoxy adhesive or the silicon adhesive is used and coated by means of spraying or printing, so that the joining property and the adhesion property of the metallic plate 1 with the biodegradable plastics described later can be enhanced.

As depicted in FIG. 1D, the metallic plate 1, on the inner face of which is coated with the adhesive 2, is fitted into the metallic mold 10 formed out of the female metallic mold 11 and the male metallic mold 12. At this time, an outer face of the metallic plate 1 is fitted into a recess portion of the female metallic mold 11 of the metallic mold 10 without leaving any gap. In this case, a profile of the male metallic mold 12 on the side of the female metallic mold 11 is formed into a profile so that the cavity 13 can be formed between the male metallic mold 12 and the female metallic mold 11 when the male metallic mold 12 is set on the female metallic mold 11.

Into this cavity 13, the biodegradable plastics are poured (injected) and cooled. When the metallic mold 10 is disassembled, as depicted in FIG. 1E, the compound housing 30, the outside of which is composed of the metallic plate 1 and the inside of which is composed of the biodegradable plastics 3, is completed. Concerning the biodegradable plastics 3, it is possible to use polylactate resin or acetate cellulose resin.

Concerning the composite housing 30 made as described above, since the heat conduction of the metallic plate 1 is excellent, the heat generated by the electronic parts in the housing is radiated and the biodegradable plastics 3 provides a heat insulating effect, i.e., the respective characteristics of the metallic plate 1 and the biodegradable plastics 3 can be utilized. Although the heat radiating effect of the metallic plate 1 changes by the heat conductivity and the plate thickness of the metallic plate 1, it is about 0.1 to 100° C. Although the heat insulating effect of the biodegradable plastics 3 changes by the thickness, it is in the range 0.1 to 10° C. The electromagnetic shielding effect of the metallic plate 1 is not more than 60 dB.

At the time of scrapping or recycling the composite housing 30 manufactured as described above, when heat is given to the composite housing 30 by a drier or in a constant temperature tank, the adhesive 2 is melted. Therefore, the metallic plate 1 and the biodegradable plastics 3 can be easily separated from each other without using a driver or a hammer. Therefore, after the separation of the metallic plate 1 from the biodegradable plastics 3, it is possible to melt and reuse the metallic plate 1 and the biodegradable plastics 3 can be easily recycled when it is smashed and buried in the ground because the biodegradable plastics 3 returned to the earth in one or two years after they have been buried. In the case of thermal recycling, carbonic acid gas, the volume of which is only a half of that of petroleum plastics, is generated. Therefore, it is advantageous in the environmental conservation.

In order to manufacture the composite housing 30 described above, the metallic plates 1 of three types, the adhesive 2 of three types and the biodegradable plastics 3 of two types were prepared and were combined with each other and the forming bodies of 18 types were manufactured. Materials of the metallic plate 1 were three types of aluminum, magnesium and stainless steel (iron alloy). Materials of the adhesive 2 were three types of acrylic adhesive, epoxy adhesive and silicon adhesive. Materials of the biodegradable plastics were two types of polylactate resin and acetate cellulose resin. With respect to the respective forming bodies of 18 types, the adhesion property of the metallic plate 1 with the biodegradable plastics was inspected. As a result of the inspection, it was confirmed that the adhesion property was excellent in all cases.

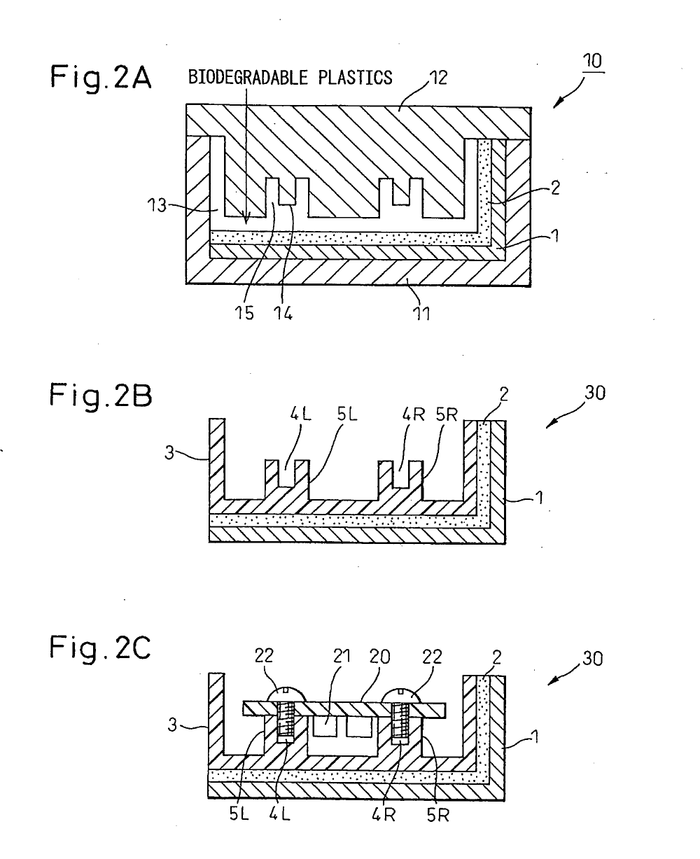

FIGS. 2A to 2C are views depicting a manufacturing process of the composite housing of the second embodiment of the present invention. Processes from folding the metallic plate 1 to coating the adhesive 2 on the inner face are the same as those depicted in FIGS. 1A, 1B and 1C. Therefore, the processes from folding the metallic plate 1 to coating the adhesive 2 on the inner face are omitted here. In the second embodiment, as depicted in FIG. 2A, the cavity 15 for a boss having the protrusion 14 for a screw is provided in the male metallic mold 12 of the metallic mold 10 into which the metallic plate 1, on the inner face of which the adhesive 2 is coated, is fitted. In order to attach the circuit board described later to the cavity 15 for a boss, at least two cavities 15 for a boss must be provided.

When the biodegradable plastics are poured (injected) into the cavity 13 and the cavity 15 for a boss depicted in FIG. 2A and cooled and then the metallic mold 10 is disassembled, the composite housing 30 depicted in FIG. 2B is completed, the outside of which is formed out of the metallic plate 1, the inside of which is formed out of the biodegradable plastics 3, and which has the bosses 5L, 5R having the screw holes 4L, 4R inside. As depicted in FIG. 2C, the circuit board 20, on which the electronic parts 21 of heat generating bodies are mounted, is attached to the bosses 5L, 5R by the screws 22.

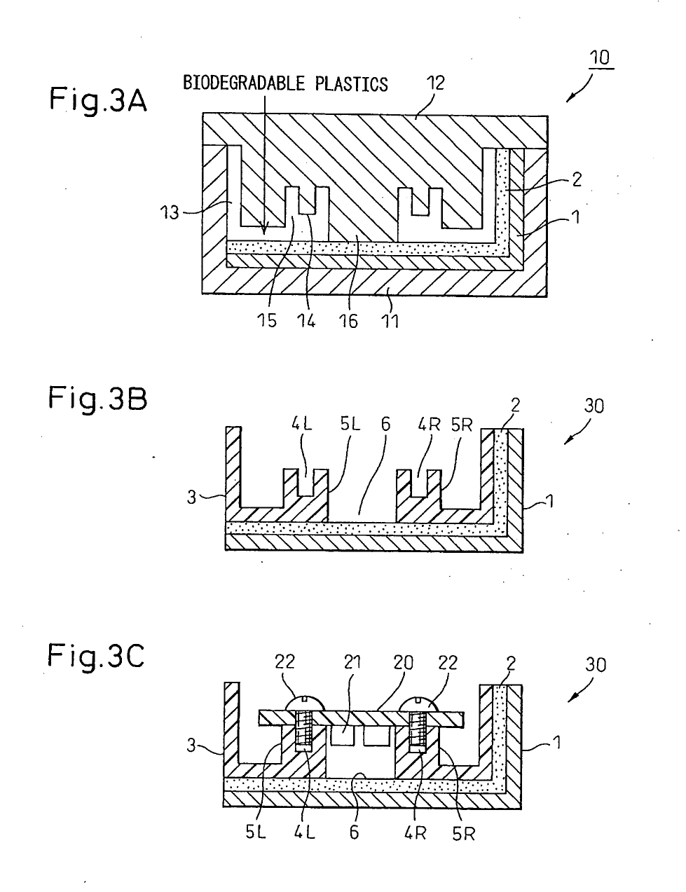

FIGS. 3A to 3C are views depicting a manufacturing process of the composite housing of the third embodiment of the present invention. Processes from folding the metallic plate 1 to coating the adhesive 2 on the inner face are the same as those depicted in FIGS. 1A, 1B and 1C. Therefore, the processes from folding the metallic plate 1 to coating the adhesive 2 on the inner face are omitted here. In the third embodiment, as depicted in FIG. 3A, the cavity 15 for a boss having the protrusion 14 for a screw is provided in the male metallic mold 12 of the metallic mold 10 into which the metallic plate 1, on the inner face of which the adhesive 2 is coated, is fitted. In the third embodiment, the protrusion 16 is provided which is formed when a portion of the male metallic mold 12 is extended to a portion of the layer of the adhesive 2. This protrusion 16 is used for forming a communication hole described later. Therefore, this protrusion 16 is formed in the neighborhood of the heat generating portion which generates heat when the circuit board is attached.

When the biodegradable plastics are poured into the cavity 13 and the cavity 15 for a boss depicted in FIG. 3A and cooled and then the metallic mold 10 is disassembled, the composite housing 30 depicted in FIG. 3B is completed, the outside of which is formed out of the metallic plate 1, the inside of which is formed out of the biodegradable plastics 3, and which has the bosses 5L, 5R having the screw holes 4L, 4R inside. In this composite housing 30, the communicating hole 6 is formed in the biodegradable plastics 3.

A position of the communicating hole 6 formed in the biodegradable plastics 3 may be decided to be in a portion which is opposed to the electronic parts 21 when the circuit board 20, on which the electronic parts of the heat generating body are mounted, is attached to the bosses 5L, 5R by the screws 22 as depicted in FIG. 3C.

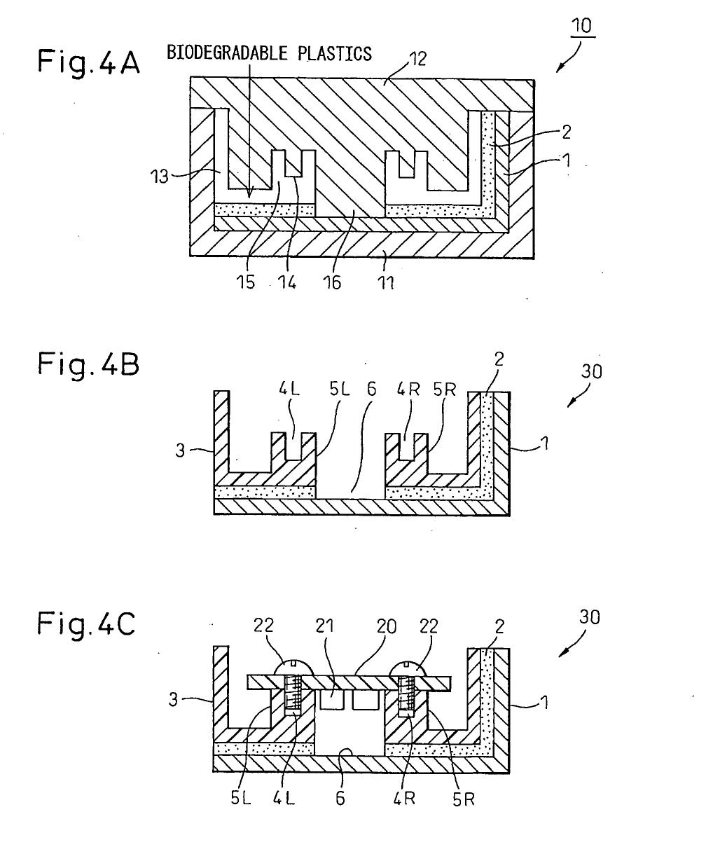

FIGS. 4A to 4C are views depicting a manufacturing process of the composite housing of the fourth embodiment of the present invention. FIGS. 4A to 4C depict a variation of the third embodiment illustrated in FIGS. 3A to 3C. In the third embodiment, as depicted in FIG. 3A, the protrusion 16, which is formed when a portion of the male metallic mold 12 is extended to a portion of the layer of the adhesive 2, is provided in the male metallic mold 12 into which the metallic plate 1, on the inner face of which the adhesive 2 is coated, is fitted. On the other hand, in the fourth embodiment, no adhesive 2 is previously coated on a back face of the metallic plate 1 corresponding to a tip portion of the protrusion 16. When the male metallic mold 12 is fitted to the female metallic mold 11, a tip portion of the protrusion 16 is tightly contacted with a back face of the metallic plate 1.

When the biodegradable plastics are poured into the cavity 13 and the cavity 15 for a boss depicted in FIG. 4A and cooled and then the metallic mold 10 is disassembled, the composite housing 30 depicted in FIG. 4B is completed, the outside of which is formed out of the metallic plate 1, the inside of which is formed out of the biodegradable plastics 3, and which has the bosses 5L, 5R having the screw holes 4L, 4R inside. In this composite housing 30, the communicating hole 6 is formed in the biodegradable plastics 3 and the metallic plate 1 is exposed into this communicating hole 6.

A position of the communicating hole 6 formed in the biodegradable plastics 3 is in a portion which is opposed to the electronic parts 21 when the circuit board 20, on which the electronic parts of the heat generating body are mounted, is attached to the bosses 5L, 5R by the screws 22 as depicted in FIG. 4C. Since the heat is directly conducted from the electronic parts 21 to the metallic plate 1, the heat radiating effect is high.

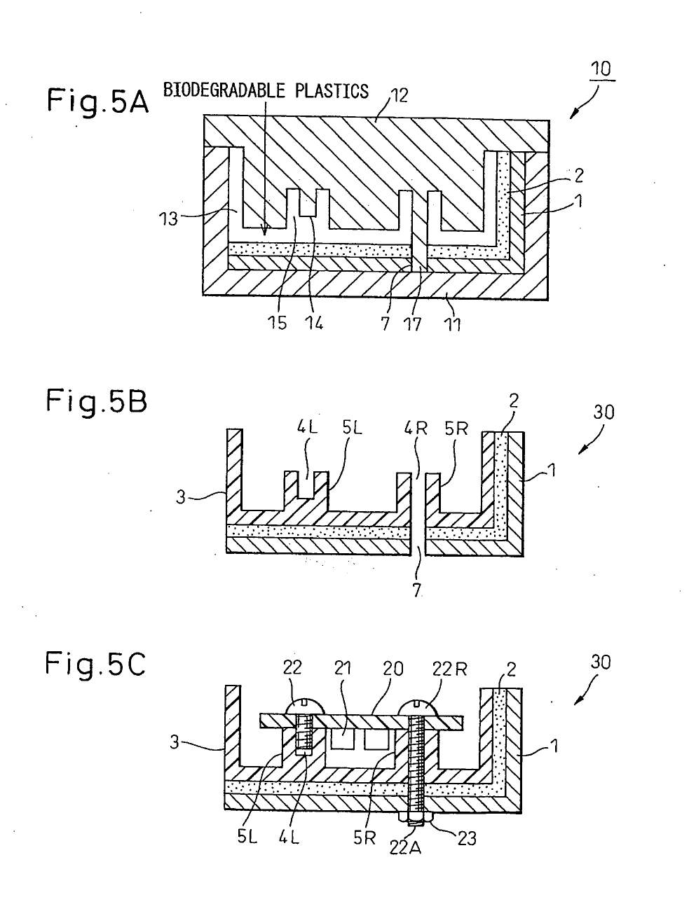

FIGS. 5A to 5C are views depicting a manufacturing process of the composite housing of the fifth embodiment of the present invention. FIGS. 5A to 5C depict a variation of the second embodiment illustrated in FIG. 2A to 2C. In the fifth embodiment, in a portion of the metallic plate 1 opposed to the protrusion 14 for a screw hole provided in the male metallic mold 12 of the metallic mold 10 for forming the screw hole 4R illustrated in FIG. 2A, the through-hole 7 is formed. The protrusion 14 for a screw hole used for forming the screw hole 4R is extended and formed into the through-hole insertion protrusion 17 inserted into this through-hole 7. When the male metallic mold 12 is fitted to the female metallic mold 11, a tip portion of the protrusion 17 is tightly contacted with the back face of the metallic plate 1.

When the biodegradable plastics are poured into the cavity 13 and the cavity 15 for a boss depicted in FIG. 5A and cooled and then the metallic mold 10 is disassembled, the composite housing 30 depicted in FIG. 2B is completed, the outside of which is formed out of the metallic plate 1, the inside of which is formed out of the biodegradable plastics 3, and which has the bosses 5L, 5R having the screw holes 4L, 4R inside. In the composite housing 30 of the fifth embodiment, only the screw hole 4R of the boss 5R is extended and communicated with the through-hole 7 provided on the metallic plate 1.

In the fifth embodiment, as depicted in FIG. 5C, when the circuit board 20 is set at the bosses 5L, 5R of the composite housing 30, the long screw 22R, the axial length of which is long, is attached to the screw hole 4R of the boss 5R. However, the usual screw 22 is attached to the boss 5L in the same manner as that of the second embodiment. The tip portion 22A of the long screw 22R passes through the through-hole 7 provided on the metallic plate 1 of the composite housing 30 and is fixed on the outside of the metallic plate 1 by the nut 23.

As a result, when the circuit board 20, on which the electronic parts of the heat generating body are mounted, is attached to the boss 5 by the screws 22, 22R, the heat generated by the electronic parts 21 is conducted from the long screw 22R to the nut 23 and directly conducted to the metallic plate 1. Therefore, the heat radiating effect of the composite housing 30 is high.

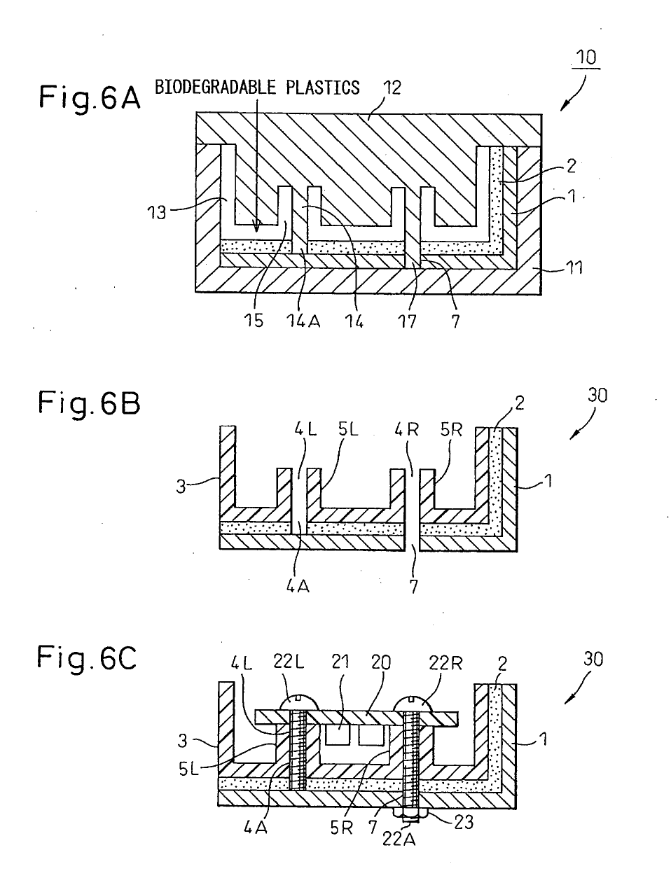

FIGS. 6A to 6C are views depicting a manufacturing process of the composite housing of the sixth embodiment of the present invention. FIGS. 6A to 6C depict a variation of the fifth embodiment illustrated in FIGS. 5A to 5C. In the sixth embodiment, in addition to the constitution of the composite housing 30 of the fifth embodiment illustrated in FIGS. 5A to 5C, as depicted in FIG. 6B, the screw hole 4L of the boss 5L is extended and extending portion 4A reaches a back face of the metallic plate 1.

In order to manufacture the composite housing 30 composed as depicted in FIG. 6B, as depicted in FIG. 6A, the extending portion 17A is provided in the protrusion 14 for a screw hole provided in the male metallic mold 12 of the metallic mold 10 so as to form the screw hole 4L. A tip portion of the extending portion 17A is tightly contacted with the back face of the metallic plate 1 when the male metallic mold 12 is fitted to the female metallic mold 11.

In the sixth embodiment, as depicted in FIG. 6C, when the circuit board 20 is set at the bosses 5L, 5R, the screw 22L, the axial length of which is somewhat long so that it can be extended from the circuit board 20 to the metallic plate 1, is attached to the boss 5L. A tip portion of the screw 22L comes into contact with the metallic plate 1. The screw 22R, the axial length of which is long, is attached into the screw hole 4R of the boss 5R. The tip portion 22A of this long screw 22R passes through the through-hole 7 provided on the metallic plate 1 and is fixed by the nut 23 on the outside of the metallic plate 1.

As a result, when the circuit board 20, on which the electronic parts 21 of the heat generating body are mounted, is attached to the bosses 5L, 5R by the somewhat long screw 22L and the long screw 22R, the heat generated by the electronic parts 21 is directly conducted to the metallic plate 1 through the somewhat long screw 22L. At the same time, the heat generated by the electronic parts 21 is conducted to the metallic plate 1 through the long screw 22R and the nut 23. Therefore, the heat radiating effect is high.

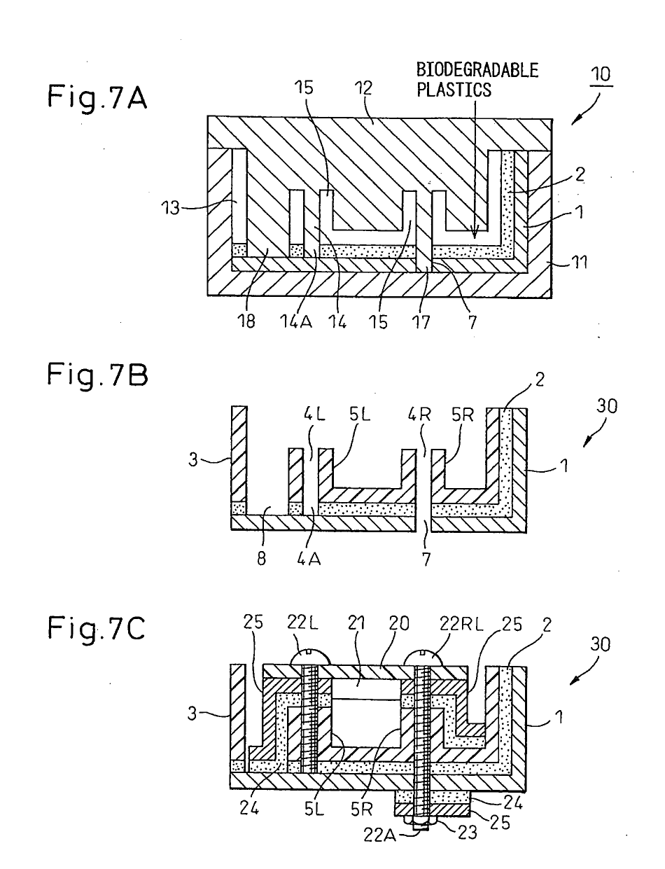

FIGS. 7A to 7C are views depicting a manufacturing process of the composite housing of the seventh embodiment of the present invention. FIGS. 7A to 7C depict a variation of the sixth embodiment illustrated in FIGS. 6A to 6C. In the seventh embodiment, in addition to the constitution of the composite housing 30 of the sixth embodiment illustrated in FIGS. 6A to 6C, as depicted in FIG. 7B, the heat radiating portion 8 is provided on the side of the boss 5L.

In order to manufacture the composite housing 30 depicted in FIG. 7B, as depicted in FIG. 7A, in order to form the boss 5L, a side portion of the cavity 15 for a boss provided in the male metallic mold 12 of the metallic mold 10 is extended as the protrusion 18 for forming a heat radiating portion. A tip portion of the protrusion 18 for forming a heat radiating portion is tightly contacted with a back face of the metallic plate 1 when the male metallic mold 12 is fitted into the female metallic mold 11.

In the seventh embodiment, as depicted in FIG. 7C, the metallic tape 25 attached with the adhesive 24 is interposed between top faces of the bosses 5L, 5R and the circuit board 20 and stuck on an inner face of the biodegradable plastics 3 and in the heat radiating portion 8 being directed from the top faces of the bosses 5L, 5R to an outer circumference of the composite housing 30. The circuit board 20 is set on the bosses 5L, 5R while the metallic tape 25 is being interposed between the circuit board 20 and the bosses 5L, 5R. The screw 22L, the axial length of which is somewhat long so that it can extend from the circuit board 20 to the metallic plate 1, is attached to the boss 5L and a tip portion of the screw 22L is contacted with the metallic plate 1. The screw 22RL, the axial length of which is much longer, is attached to the screw hole 4R of the boss 5R. The tip portion 22A of this long screw 22RL passes through the through-hole 7 provided on the metallic plate 1 and is inserted into the metallic tape 25 attached with the adhesive 24 outside the metallic plate 1. Then, this long screw 22RL is fixed by the nut 23.

As a result, when the circuit board 20, on which the electronic parts of a heat generating body are mounted, is attached to the bosses 5L, 5R by the somewhat long screw 22L and the much longer screw 22RL, the heat generated by the electronic parts 21 conducts to the somewhat long screw 22L and the much longer screw 22RL and directly conducts to the metallic plate 1. At the same time, the heat is also radiated by the nut 23 and the metallic tape 25. Therefore, the heat radiating effect is further enhanced.

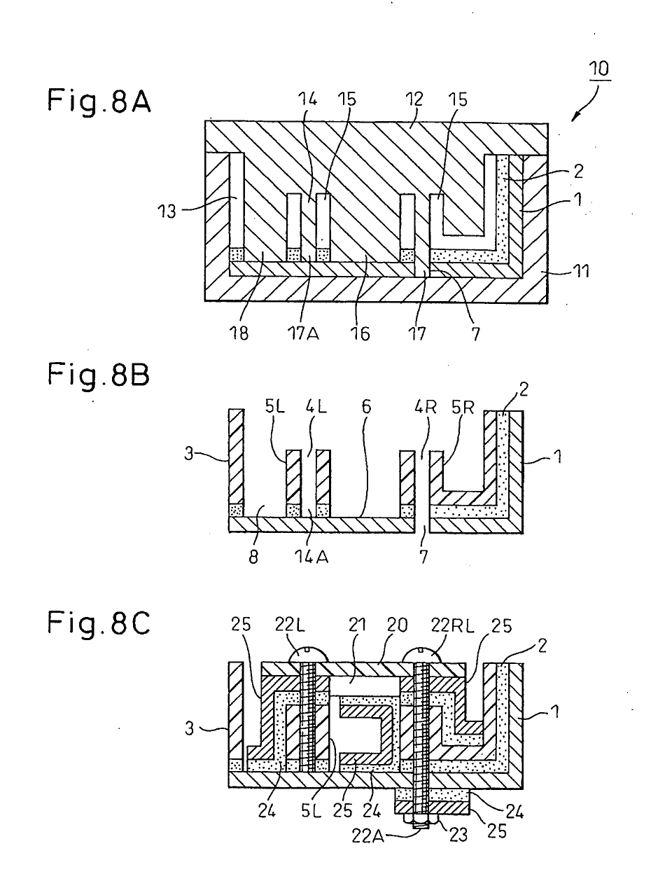

FIGS. 8A to 8C are views depicting a manufacturing process of the composite housing of the eighth embodiment of the present invention. FIG. 8A to 8C depict a variation of the seventh embodiment illustrated in FIGS. 7A to 7C. In the eighth embodiment, in addition to the constitution of the composite housing 30 of the seventh embodiment illustrated in FIGS. 7A to 7C, as depicted in FIG. 8B, the communicating hole 6, in which the biodegradable plastics 3 is not provided, is formed in a region between the bosses 5L and 5R.

In order to manufacture the composite housing 30 depicted in FIGS. 8A to 8C, as depicted in FIG. 8A, a portion formed between two cavities 15 for a boss of the male metallic mold 12 of the metallic mold 10 is extended as the protrusion 16 for forming a communicating hole. A tip portion of the protrusion 16 for forming a communicating hole is tightly contacted with a back face of the metallic plate 1 when the male metallic mold 12 is fitted into the female metallic mold 11.

In the eighth embodiment, as depicted in FIG. 8C, in addition to the constitution depicted in FIG. 7C, the metallic tape 25 attached with the adhesive 24 is stuck between the electronic parts provided on the back face of the circuit board 20 and the back face of the metallic plate 1 exposed to the communicating passage 6. The other constitution of the eighth embodiment is the same as that of the seventh embodiment.

As a result, when the circuit board 20, on which the electronic parts 21 of the heat generating body are mounted, is attached to the boss 5 by the somewhat long screw 22L and the much longer screw 22RL, the heat generated by the electronic parts 21 directly conducts to the metallic plate 1 through the somewhat long screw 22L and the much longer screw 22RL. At the same time, the heat is radiated by the nut 23 and the metallic tapes 25 arranged at a plurality of portions. Therefore, the heat radiating effect is further enhanced.

When the heat radiating means such as a screw portion or a metallic tape is added to the metallic plate 1 composing the composite housing 30, it is possible to enhance not only the heat radiating effect but also the earth and electromagnetic wave shielding effect as compared with a case in which the metallic plate 1 is singly used for composing the composite housing 30. According to the result of the experiment, it could be confirmed that the damping effect of not more than 60 dB was provided.

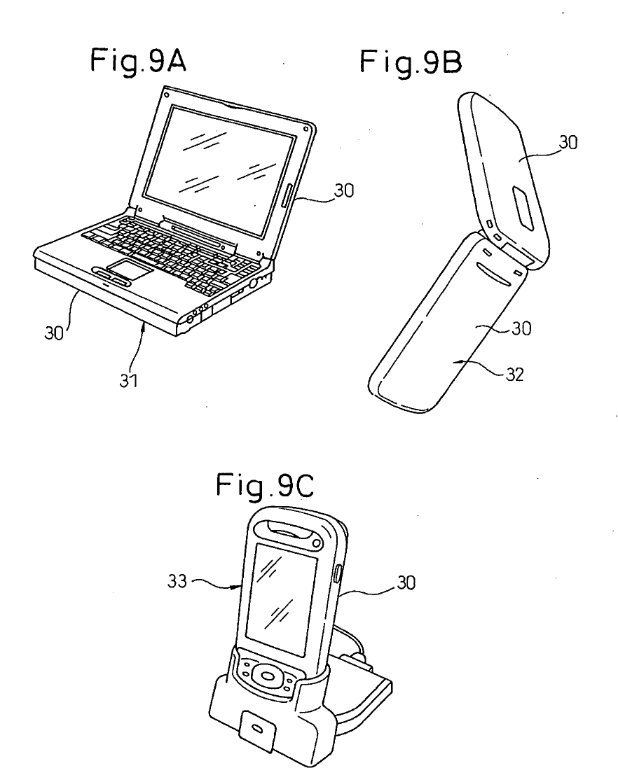

FIGS. 9A to 9C are views depicting an example of the use of the composite housing 30 to which the biodegradable plastics of the present invention is applied. FIG. 9A depicts an example in which the composite housing 30 of the present invention is used for a lower cover and a back cover of the main body of the note type personal computer 31. FIG. 9B depicts an example in which the composite housing 30 of the present invention is used for a lower cover and an upper cover of the main body of the mobile telephone 32. FIG. 9C is a perspective view depicting an example in which the composite housing 30 of the present invention is used for a back cover of the main body of PDA (Personal Digital Assistant) 33.

The use of the composite housing of the present invention is not limited to the above. For example, the composite housing of the present invention is used for a housing of an electric appliance, a front fender of an automobile or a rear spoiler of a sporty type automobile. Further, the composite housing of the present invention is used for an outer panel of an outer wall of a house.

1. A composite housing using biodegradable plastics comprising: a metallic plate; a layer of adhesive coated on an inner face of the metallic plate; and a layer of biodegradable plastics laminated on a coating face of the layer of adhesive coated on the metallic plate, wherein
the metallic plate is formed into a profile of a housing, an inner face of the formed metallic plate is coated with adhesive, the metallic plate is fitted into a female metallic mold, and biodegradable plastics are injected into a cavity formed between the adhesive coating face of the metallic plate and a male metallic mold so that the metallic plate and the biodegradable plastics are integrated with each other into one body in the metallic mold.

2. The composite housing using biodegradable plastics according to claim 1, wherein
the male metallic mold of a predetermined portion in the metallic mold is tightly contacted with an adhesive coating face of the metallic plate so as to form a discontinuous portion in a cavity in the metallic mold and the metallic plate is exposed to a portion corresponding to the discontinuous portion of the cavity on the inner face of the composite housing which has been integrally molded into one body.

3. The composite housing using biodegradable plastics according to claim 1, wherein
at least two cavities for forming a boss having a screw hole are provided in the cavity in the metallic mold, and bosses, to which a circuit board on which electronic parts are mounted can be attached, are formed on an inner face of the composite housing after the completion of integral forming.

4. The composite housing using biodegradable plastics according to claim 3, wherein
the male metallic mold of a predetermined portion in the metallic mold is tightly contacted with the adhesive coating face of the metallic plate so as to form a discontinuous portion in the cavity in the metallic mold, and the metallic plate is exposed to a portion corresponding to the discontinuous portion of the cavity on an inner face of the composite housing after the completion of forming.

5. The composite housing using biodegradable plastics according to claim 3, wherein
in the case where an opening portion is provided in a portion corresponding to the screw hole of the boss of the metallic plate which has been worked,
a portion of the male metallic mold for forming the screw hole of the boss is extended to the opening portion, and
the screw hole of the boss after the completion of forming is communicated with the opening portion of the metallic plate.

6. The composite housing using biodegradable plastics according to claim 5, wherein
the length of the screw for fixing the circuit board to the boss is made to be the length protruding from the opening portion of the metallic plate.

7. The composite housing using biodegradable plastics according to claim 6, wherein
a tip portion of the screw protruding from the opening portion of the metallic plate is engaged with a nut.

8. The composite housing using biodegradable plastics according to claim 7, wherein
a metallic tape for radiating heat is inserted into between the nut and the metallic plate.

9. The composite housing using biodegradable plastics according to claim 4, wherein
in the case where an opening portion is provided in a portion corresponding to the screw hole of the boss of the metallic plate which has been worked,
a portion of the male metallic mold for forming the screw hole of the boss is extended to the opening portion, and
the screw hole of the boss after the completion of forming is communicated with the opening portion of the metallic plate.

10. The composite housing using biodegradable plastics according to claim 9, wherein
the length of the screw for fixing the circuit board to the boss is made to be the length protruding from the opening portion of the metallic plate.

11. The composite housing using biodegradable plastics according to claim 10, wherein
a tip portion of the screw protruding from the opening portion of the metallic plate is engaged with a nut.

12. The composite housing using biodegradable plastics according to claim 11, wherein
a metallic tape for radiating heat is inserted into between the nut and the metallic plate.

13. The composite housing using biodegradable plastics according to claim 12, wherein
the heat generating body and the exposed portion of the metallic plate are connected with each other by a metallic tape for radiating heat.

14. The composite housing using biodegradable plastics according to claim 8, wherein
the metallic tape is made of one of aluminum, copper, brass, nickel, chromium, lead and alloy of at least two of the metals described above.

15. The composite housing using biodegradable plastics according to claim 1, wherein
the metallic plate is made of aluminum, copper, nickel, chromium, cobalt, zinc, titanium, magnesium, tin, gold, silver, platinum, metal of platinum group and alloy of at least two of the metals described above.

16. The composite housing using biodegradable plastics according to claim 1, wherein
the adhesive is one of acrylic adhesive, epoxy adhesive and silicon adhesive.

17. The composite housing using biodegradable plastics according to claim 1, wherein
the biodegradable plastics are made of one of polylactate cellulose resin and acetate cellulose resin.

18. The composite housing using biodegradable plastics according to claim 1, wherein
the housing is one of the housings of a personal computer, a mobile phone, an electric appliance, an office automation device, a pneumatic characteristic improving member and a wall member of a house.

19. A method of manufacturing a composite housing using biodegradable plastics which includes a metallic plate, a layer of adhesive coated on an inner face of the metallic plate, and a layer of biodegradable plastics laminated on a coating face of the layer of adhesive coated on the metallic plate, the method of manufacturing the composite housing using biodegradable plastics comprising:
forming the metallic plate into a profile of a housing;
coating adhesive on an inner face of the formed metallic plate;
fitting the metallic plate, on the inner face of which adhesive is coated, into a female metallic mold;
injecting biodegradable plastics into a cavity between an adhesive coating face of the metallic plate and a male metallic mold; and
taking out a compound housing from the metallic mold after cooling.

20. The method of manufacturing a composite housing using biodegradable plastics according to claim 19, wherein
at least two cavities for forming a boss having a screw hole are provided in a cavity formed in the metallic mold so that the bosses to which a circuit board, on which electronic parts are mounted, can be attached on an inner face of the composite housing after the completion of integral forming.
